(19) United States
(12) Patent Application Publication
(10) Pub. No.: US 2006/0082422 A1
(43) Pub. Date: Apr. 20, 2006

(54) Connection structure of high frequency lines and optical transmission module using the connection structure

(75) Inventors: Masayoshi Yagyu, Hanno (JP); Tatsuya Saito, Kunitachi (JP); Shigeo Oomae, Hadano (JP); Mitsuo Akashi, Chigasaki (JP)

Correspondence Address: MATTINGLY, STANGER, MALUR & BRUNDIDGE, P.C., 1800 DIAGONAL ROAD, SUITE 370, ALEXANDRIA, VA, 22314, US

(73) Assignees: HITACHI, LTD; OPNEXT JAPAN, INC.

(21) Appl. No.: 11/240,455

(22) Filed: Oct. 3, 2005

Related U.S. Application Data
(63) Continuation of application No. 10/628,234, filed on Jul. 29, 2003, now abandoned.

(30) Foreign Application Priority Data
Feb. 14, 2003 (JP) 2003-035934

(51) Int. Cl. H03H 7/38

(52) U.S. Cl. 333/33

(57) ABSTRACT

A connection structure is applied to mutually connect a first and a second transmission line that is planar in shape and that has a ground conductor on a second main surface, such as a microstrip line or a coplanar line with a ground. The first and the second transmission lines are superposed one upon the other, and their signal wiring patterns are electrically connected, as are their ground conductors. An end surface of the first transmission line is substantially covered by a conductor layer connected to the ground conductor. The connection structure can achieve good signal transmission characteristics up to high-frequency bands on the order of several tens of gigahertz.

This is a continuation application of U.S. Ser. No. 10/628,234, filed Jul. 29, 2003.

### BACKGROUND OF THE INVENTION

1. Field of the Invention

The present invention relates to a technique for connection between transmission lines for transmitting signals at high speeds. Particularly, it relates to a technique for connection between transmission lines suitable for network apparatuses which transmit data at rates on the order of several tens of Gbps.

2. Background Art

Network apparatuses for high-speed data transmission are equipped with many components for signal processing, and many transmission lines are used for connection between these components. Types of transmission lines are different for individual components, such as coaxial cables, strip lines, and coplanar lines.

Referring to FIGS. 1A to 2D, an example of a structure for connecting two transmission lines according to the prior art will be described. One of the transmission lines is a coplanar line with a ground and will be referred to as a component 1. The other of the transmission lines is a microstrip line and will be referred to as a component 2. By connecting the signal wiring patterns of the two components 1 and 2 and by connecting the ground conductors of the two components 1 and 2, the two transmission lines are connected.

As shown in FIG. 1A, the lower component 1 includes a dielectric 103, a signal wiring pattern 101 and a ground conductor 104 both disposed on an upper surface of the dielectric 103, and a ground conductor 102 disposed on an lower surface of the dielectric 103. The upper component 2 includes a dielectric 203, a signal wiring pattern 201 disposed on an upper surface of the dielectric 203, and a ground conductor 202 disposed on a lower surface of the dielectric 203.

As shown in FIG. 1B, on the lower surface of the component 2, a conductor pattern 207 is disposed. As shown in FIG. 1C, the conductor pattern 207 is connected to the signal wiring pattern 201 on the upper surface via a conductor 205 disposed in a through-hole formed in the dielectric 203.

Solders 121 and 122 are disposed on the conductor pattern 207 and the ground conductor 202 on the lower surface of component 2, respectively. These solders function to electrically and mechanically connect the conductors of the components 1 and 2.

Referring to FIG. 2A, the components 1 and 2 are arranged such that an end of the component 2 is superposed on an end of the component 1. Now referring to FIG. 2B, the signal wiring pattern 101 on the upper surface of the component 1 is electrically connected to the conductor pattern 207 on the lower surface of the component 2 via the solder 121. The ground conductor 104 on the upper surface of the component 1 is electrically connected to the ground conductor 202 on the lower surface of the component 2 via the solder 122, as shown in FIG. 2C. The ground conductors 104 and 102 of the component 1 are connected to each other via a conductor 106 in a through-hole formed in the dielectric 103.

Referring to FIG. 2D, the signal wiring pattern 101 on the upper surface of the component 1 is electrically connected to the signal wiring pattern 201 on the upper surface of the component 2 via the solder 121, conductor pattern 207, and conductor 205 in through-hole. Thus, an electric signal can be transmitted from the signal wiring pattern 101 on the upper surface of the component 1 to the signal wiring pattern 201 on the upper surface of the component 2.

This or other similar structures for connecting transmission lines are disclosed in U.S. Pat. No. 6,501,352, JP Patent Publication (Kokai) Nos. 2001-358246 A, 2000-286614 A, 2000-77902 A, and 9-283574 A (1997).

The conventional structure for connecting transmission lines as shown in FIGS. 1A to 2D has such a problem that when an electric signal is transmitted using this structure, the signal transmission characteristics deteriorate particularly in frequency bands of several tens of GHz. The inventors' analysis indicated that due to the discontinuous structure of the connecting portion, part of high-frequency signals are emitted to the air from the transmission lines.

### SUMMARY OF THE INVENTION

It is an object of the invention to provide a structure for connecting transmission lines that can prevent the emission of radio wave of a high-frequency signal at the connecting portion.

It is another object of the invention to provide a transmission line structure having good signal transmission characteristics up to high-frequency bands.

According to a representative embodiment of the invention, the present invention is characterized in that in a connection structure for transmitting an electrical signal from a signal wiring pattern of a first transmission line to that of a second transmission line, an end surface of the first transmission line is substantially covered with a conductor that is connected to a ground conductor.

More specifically, the first and the second transmission lines each include a signal wiring pattern on a first main plane of a dielectric plate, and a ground conductor on a second main plane thereof. A lower surface of the second transmission line is superposed on an upper surface of the first transmission line at the connecting portion so that the signal wiring pattern and the ground conductor of the first transmission line can be connected to the signal wiring pattern and the ground conductor of the second transmission lines, respectively. In this superposed connection structure, the dielectric plate is not exposed at the end surface of the first transmission line, but the end surface thereof is substantially covered with a conductor layer that is connected to the ground conductor.

The structure reduces the reflection of a signal at the connecting portion, so that good signal transmission characteristics can be obtained up to high-frequency regions on the order of several tens of gigahertz.

### BRIEF DESCRIPTION OF THE DRAWINGS

FIGS. 1A to 1C show an example of the connection structure for transmission lines according to the prior art. FIG. 1A is a perspective view illustrating how two transmission lines are connected. FIG. 1B is a bottom view of a component 2. FIG. 1C is a cross sectional view along line A1-A2 of the component 2.

FIGS. 2A to 2D similarly show the connection structure according to the prior art. FIG. 2A is a top view of the structure when the components 1 and 2 are connected. FIG. 2B is a cross sectional view along line B1-B2 of the components 1 and 2. FIG. 2C is a cross sectional view along line C1-C2 of the components 1 and 2. FIG. 2D is a cross sectional view along line D1-D2 of the components 1 and 2.

FIGS. 3A to 3D show the connection structure for transmission lines according to a first embodiment of the invention. FIG. 3A is a perspective view illustrating how components 3 and 4 are connected. FIG. 3B is a bottom view of the component 4. FIG. 3C is a cross sectional view along line E1-E2 of the component 4.

FIGS. 4A to 4E similarly show the first embodiment of the invention. FIG. 4A is a top view of components 3 and 4 when they are connected. FIG. 4B is a cross sectional view along line F1-F2 of the components 3 and 4. FIG. 4C is a cross sectional view along line G1-G2 of the components 3 and 4. FIG. 4D is a cross sectional view along line H1-H2 of the components 3 and 4. FIG. 4E is a cross sectional view along line i1-i2 of the components 3 and 4.

FIGS. 5A and 5B show the signal transmission characteristics of the transmission lines of the first embodiment in comparison to those of the conventional example. FIG. 5A show the frequency characteristics of signal reflectance. FIG. 5B show the frequency characteristics of signal transmittance.

FIGS. 6A to 6C show the connection structure for transmission lines according to a second embodiment of the invention. FIG. 6A is a perspective view illustrating how components 5 and 6 are connected. FIG. 6B is a bottom view of the component 6. FIG. 6C is a cross sectional view along line J1-J2 of the component 6.

FIGS. 7A to 7E similarly show the second embodiment of the invention. FIG. 7A is a top view of the components 5 and 6 when they are connected. FIG. 7B is a cross sectional view along line K1-K2 of the components 5 and 6. FIG. 7C is a cross sectional view along line L1-L2 of the components 5 and 6. FIG. 7D is a cross sectional view along line M1-M2 of the components 5 and 6. FIG. 7E is a cross sectional view along line N1-N2 of the components 5 and 6.

FIGS. 8A to 8C show the connection structure for transmission lines according to a third embodiment of the invention. FIG. 8A is a perspective view illustrating how components 7 and 8 are connected. FIG. 8B is a bottom view of the component 8. FIG. 8C is a cross sectional view along line O1-O2 of the component 8.

FIGS. 9A to 9E similarly show the third embodiment of the invention. FIG. 9A is a top view of the components 7 and 8 when they are connected. FIG. 9B is a cross sectional view along line P1-P2 of the components 7 and 8. FIG. 9C is a cross sectional view along line Q1-Q2 of the components 7 and 8. FIG. 9D is a cross sectional view along line R1-R2 of the components 7 and 8. FIG. 9E is a cross sectional view along line S1-S2 of the components 7 and 8.

FIG. 10 is a functional block diagram of an optical transmission module to which the connection structure for transmission lines according to the invention is applied.

FIG. 11 is an enlarged cross sectional view of the connection structure between devices in the optical transmission module of FIG. 10.

### DESCRIPTION OF PREFERRED EMBODIMENTS

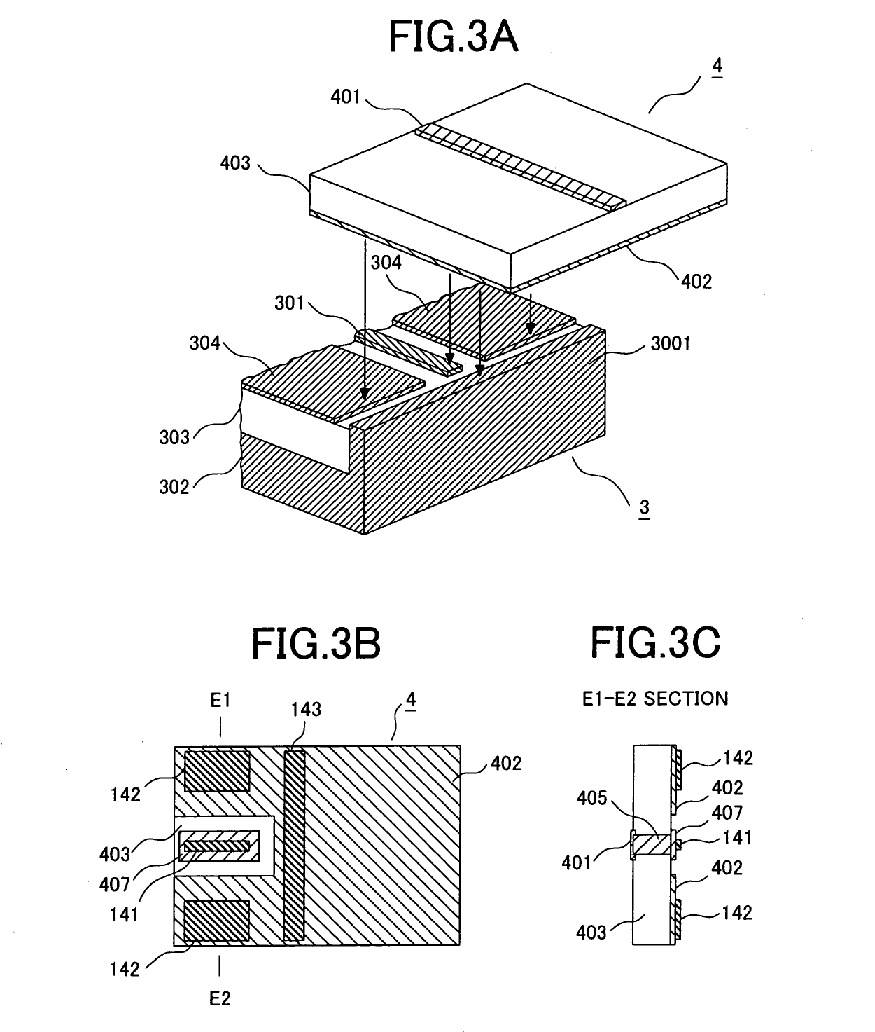

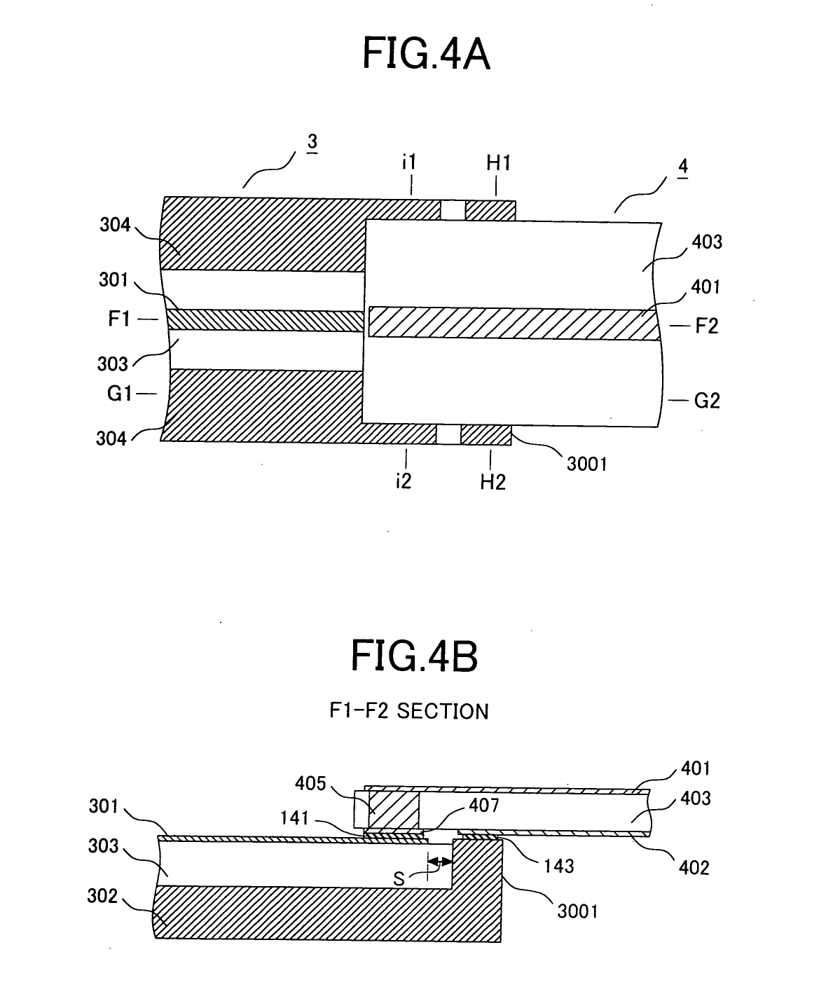

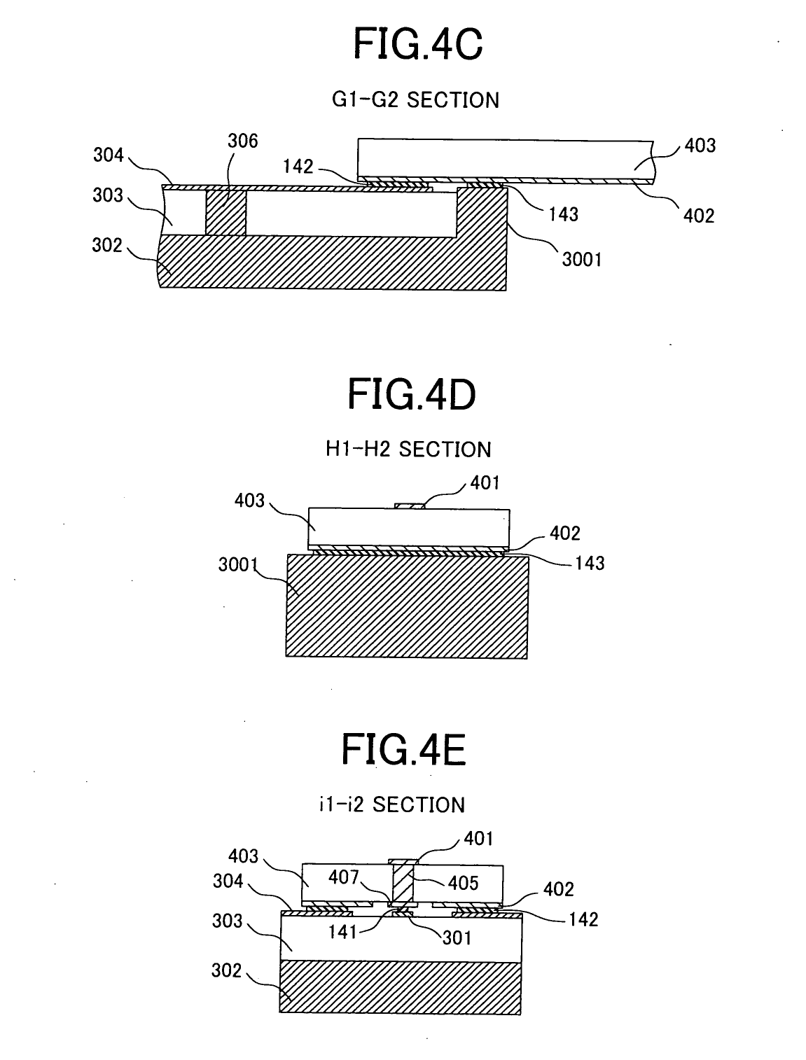

Referring to FIGS. 3A to 4E, a first embodiment of the structure and method for connecting two transmission lines according to the invention will be described.

One of transmission lines is a coplanar line with a ground and will be referred to as a component 3. The other of transmission lines is a microstrip line and will be referred to as a component 4. By connecting the signal wiring patterns of the two components 3 and 4 and by connecting the ground conductors of the two components 3 and 4, the two transmission lines are connected.

As shown in FIG. 3A, the lower component 3 includes a dielectric 303, a signal wiring pattern 301 and a ground conductor 304 both disposed on an upper surface of the dielectric 303, and a ground conductor 302 disposed on a lower surface of the dielectric 303.

In the first embodiment, the lower component 3 further includes a conductor 3001 disposed at an end surface thereof. The conductor 3001 is disposed perpendicular to the signal wiring pattern 301, such that it covers an end surface of the dielectric 303. The conductor 3001 is electrically connected to the ground conductor 302.

The upper component 4 includes a dielectric 403, a signal wiring pattern 401 disposed on an upper surface of the dielectric 403, and a ground conductor 402 disposed on a lower surface of the dielectric 403.

As shown in FIG. 3B, on a lower surface of the component 4, a conductor pattern 407 is disposed. The conductor pattern 407 is connected to the signal wiring pattern 401 via a conductor 405 in a through-hole formed in the dielectric 403, as shown in FIG. 3C.

On the conductor 407 on the lower surface of the component 4, a solder 141 is disposed, and on the ground conductor 402, solders 142 and 143 are disposed. These solders function to electrically and mechanically connect the conductors of the components 3 and 4.

Referring to FIGS. 4A to 4E, the structure and method for connecting the components 3 and 4 will be described in more detail. As shown in FIG. 4A, the two components are arranged such that an end of the component 4 is superposed on an end of the component 3. As shown in FIG. 4B, the signal wiring pattern 301 on the upper surface of the component 3 is electrically connected to the conductor pattern 407 on the lower surface of the component 4 via the solder 141. As shown in FIG. 4C, the ground conductor 304 on the upper surface of the component 3 is electrically connected to the ground conductor 402 on the lower surface of the component 4 via the solder 142. The ground conductors 304 and 302 of the component 3 are electrically connected to each other via a conductor 306 in a through-hole formed in the dielectric 303.

Further, in the first embodiment, the upper surface of the conductor 3001 of the component 3 is electrically connected to the ground conductor 402 on the lower surface of the component 4 via the solder 143, as shown in FIGS. 4B, 4C, and 4D.

Referring to FIG. 4E, the signal wiring pattern 301 on the upper surface of the component 3 is electrically connected to the signal wiring pattern 401 on the upper surface of the component 4 via the solder 141, conductor pattern 407, and a conductor 405 in a through-hole. Thus, an electric signal can be transmitted from the signal wiring pattern 301 of the component 3 to the signal wiring pattern 401 of the component 4.

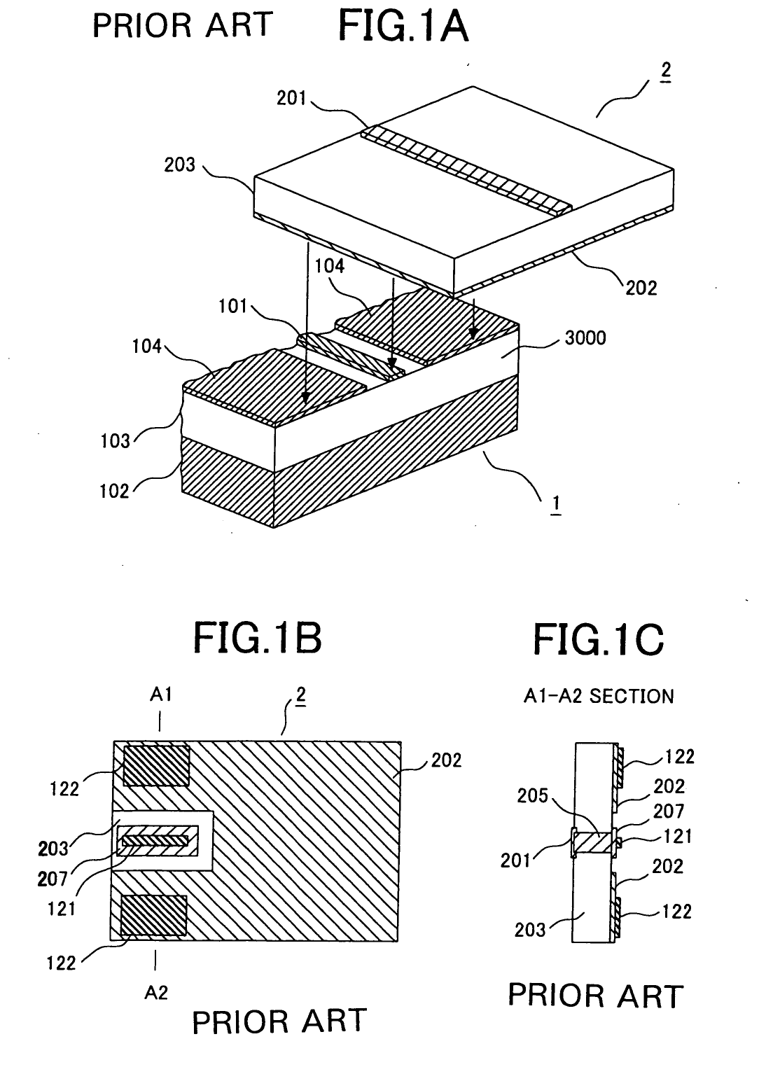

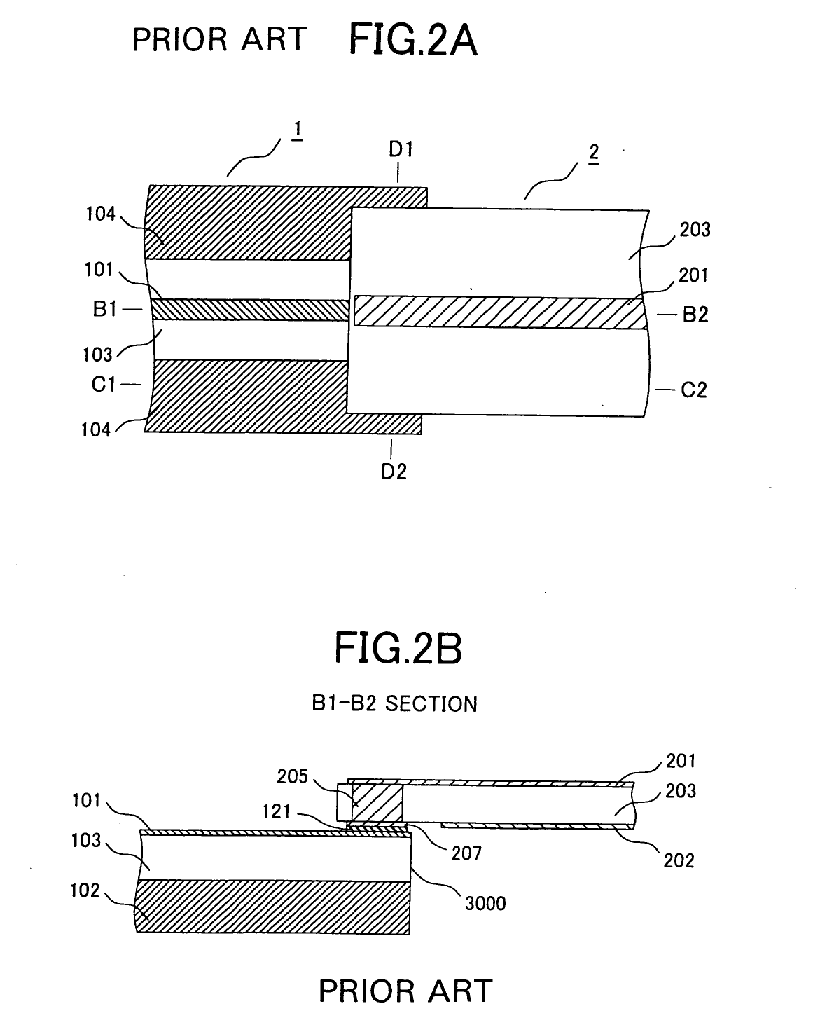

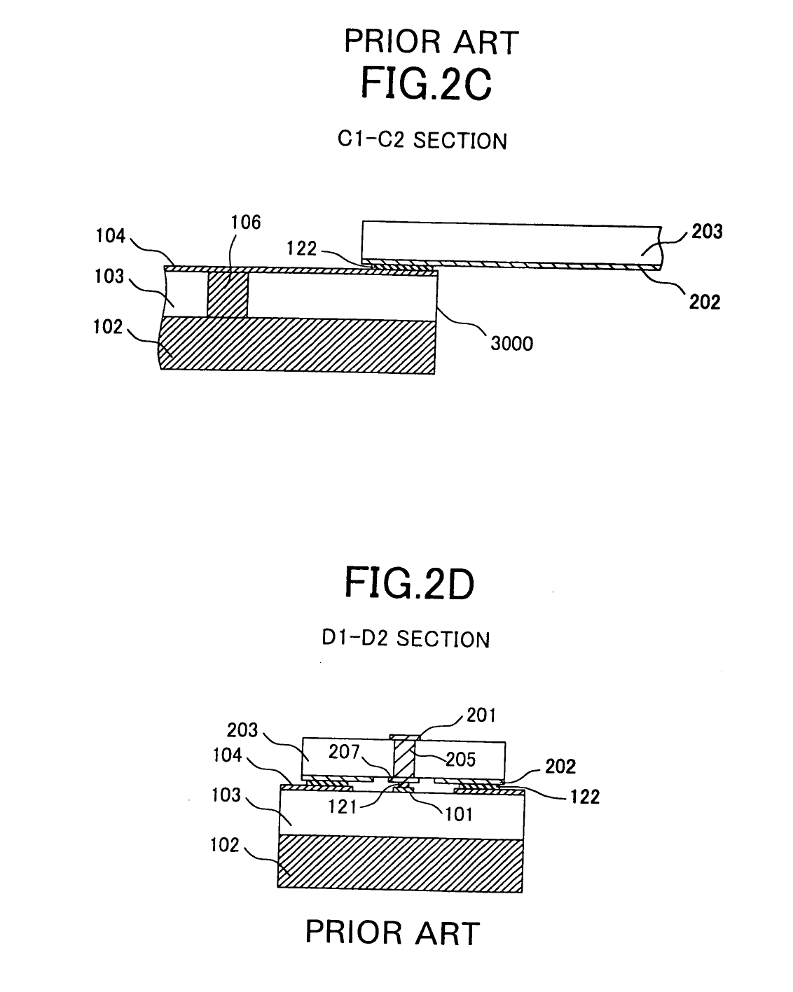

In comparison to the conventional example shown in FIGS. 1 and 2, it will be seen that the first embodiment of the invention shown in FIGS. 3A to 4E differs in that the conductor 3001 is added. The conductor 3001 is disposed on an end surface of the component 3 that corresponds to a surface 3000 of the component 1 of the conventional example. It is electrically connected to the ground conductor 302, and is also electrically connected the ground conductor 304 via a conductor 306 in a through-hole.

By disposing the conductor 3001 as the first embodiment of the invention, it can prevent the emission of radio waves from the surface 3000, which causes the deterioration in the signal transmission characteristics in high-frequency bands in the conventional example.

The distance S between the edge of the signal wiring pattern 301 and the conductor 3001 in FIG. 4B should preferably be set to be smaller than ¼ of the wavelength of the electric signal passing through the signal wiring pattern 301. For example, when the relative permittivity of the dielectric 303 is 10 and the frequency band of the electric signal passing through the signal wiring pattern 301 is 40 GHz, ¼ of the wavelength of the electric signal is about 750 μm and therefore the distance S should be set to be smaller than 750 μm.

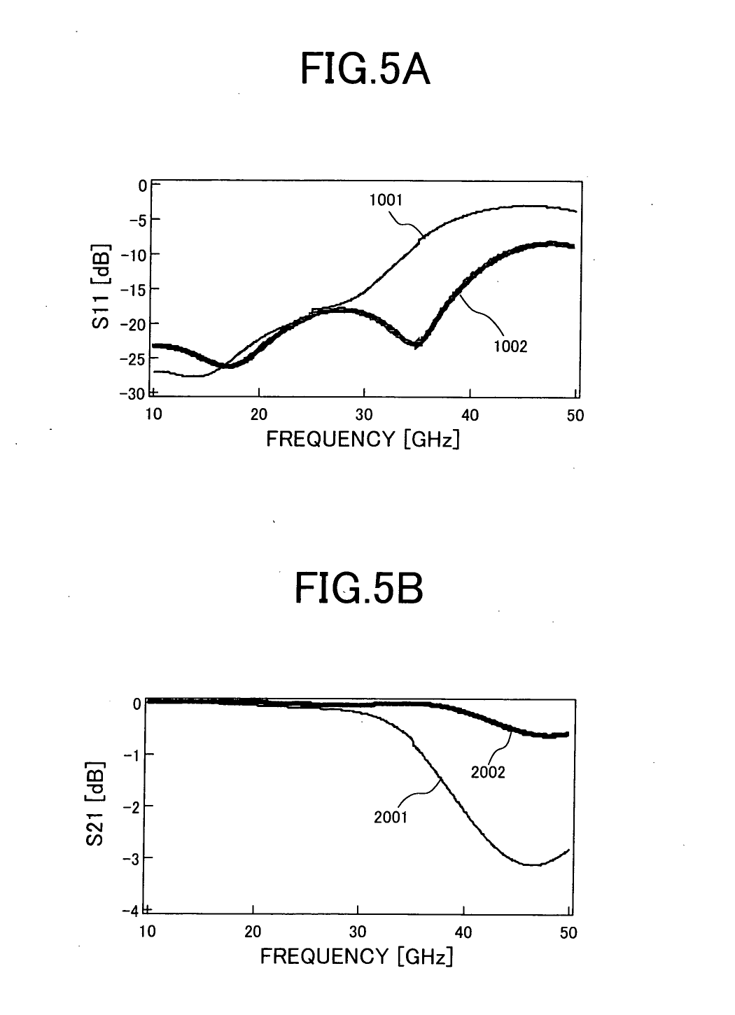

Referring to FIGS. 5A and 5B, the signal transmission characteristics of the first embodiment of the invention will be compared with those of the conventional example. FIG. 5A shows the frequency characteristics of signal reflectance. A curve 1001 indicates the characteristics of the transmission line connection structure according to the conventional example. A curve 1002 indicates the characteristics of the connection structure according to the first embodiment of the invention. FIG. 5B shows frequency characteristics of signal transmittance. A curve 2001 indicates the characteristics of the connection structure of the conventional example. A curve 2002 indicates those of the connection structure of the first embodiment. It will be seen that the connection structure of the invention can achieve lower signal reflectance and higher signal transmittance in frequency bands of over 30 GHz in particular.

The signal transmission characteristics shown in FIGS. 5A and 5B were obtained by three-dimensional electromagnetic field simulations, which employed the following values and materials:

Thickness of dielectrics 103, 303: 200 μm

Relative permittivity of dielectrics 103, 303: 10

Width of signal wiring patterns 101, 301: 150 μm

Distance between signal wiring patterns 101, 301 and ground conductors 104, 304: 225 μm

Thickness of dielectrics 203, 403: 50 μm

Relative permittivities of dielectrics 203, 403: 2, 9 respectively

Width of signal wiring patterns 201, 401: 100 μm

Distance (S in FIG. 4B) between signal wiring pattern 301 and conductor 3001: 93 μm

Material of all of the conductors: copper

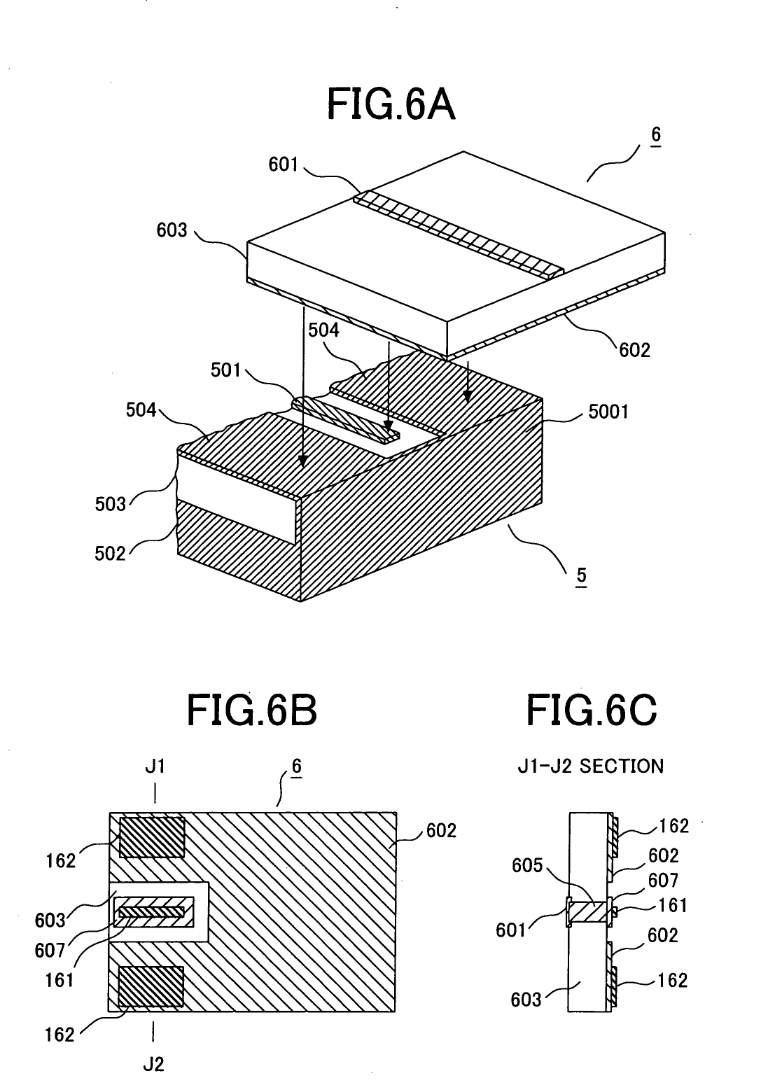

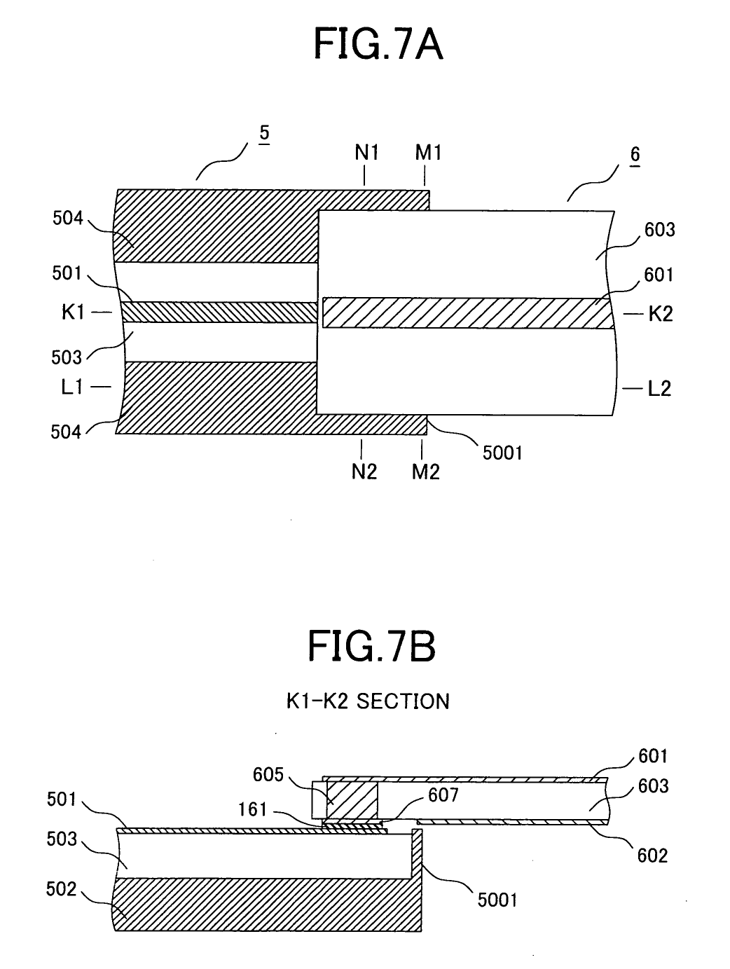

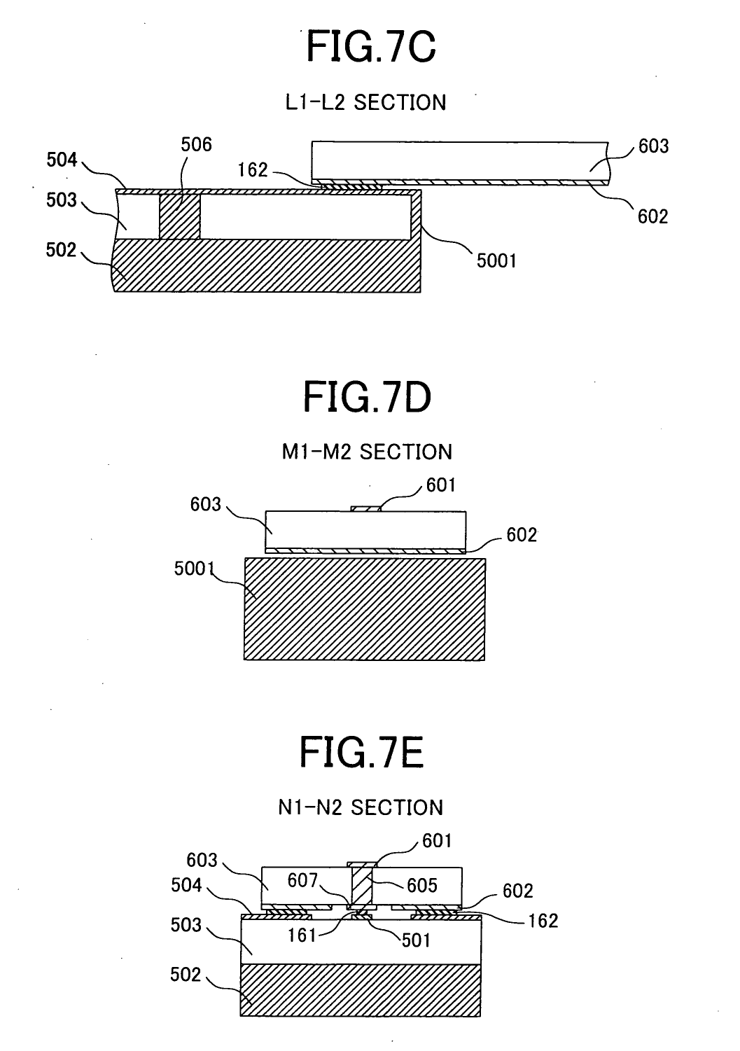

Now referring to FIGS. 6A to 7E, a second embodiment of the structure and method for connecting two transmission lines according to the invention will be described. One of transmission lines is a coplanar line with a ground and will be referred to as a component 5. The other of transmission lines is a microstrip line and will be referred to as a component 6. By connecting the signal wiring patterns of the two components 5 and 6 and by connecting the ground conductors of the two components 5 and 6, the two transmission lines are connected.

As shown in FIG. 6A, the lower component 5 includes a dielectric 503, a signal wiring pattern 501 and a ground conductor 504 both disposed at an upper surface of the dielectric 503, and a ground conductor 502 disposed on a lower surface of the dielectric 503.

In the second embodiment, the component 5 further includes a conductor 5001 disposed at an end surface thereof. The conductor 5001 is disposed perpendicular to the signal wiring pattern 501, such that it covers an end surface of the dielectric 503. The conductor 5001 is electrically connected to the ground conductors 502 and 504.

The upper component 6 includes a dielectric 603, a signal wiring pattern 601 disposed on an upper surface of the dielectric 603, and a ground conductor 602 disposed on a lower surface of the dielectric 603. The upper component 6 has a structure similar to that of the component 2 shown in FIG. 1.

As shown in FIG. 6B, a conductor pattern 607 is disposed on a lower surface of the component 6. As shown in FIG. 6C, the conductor pattern 607 is connected to a signal wiring pattern 601 via a conductor 605 in a through-hole formed in the dielectric 603.

Solders 161 and 162 are disposed on the conductor 607 and the ground conductor 602, respectively, on the lower surface of the component 6. These solders function to electrically and mechanically connect the conductors of the components 5 and 6.

Referring to FIGS. 7A to 7E, the structure and method for connecting the components 5 and 6 will be described in more detail. As shown in FIG. 7A, an end of the component 6 is superposed on an end of the component 5. As shown in FIG. 7B, the signal wiring pattern 501 on the upper surface of the component 5 is electrically connected to the conductor pattern 607 on the lower surface of the component 6 via the solder 161.

As shown in FIG. 7C, the ground conductor 504 on the upper surface of the component 5 is electrically connected to the ground conductor 602 on the lower surface of the component 6 via the solder 162. The ground conductors 504 and 502 of the component 5 are electrically connected to each other via a conductor 506 in a through-hole formed in the dielectric 503.

As shown in FIG. 7E, the signal wiring pattern 501 on the upper surface of the component 5 is electrically connected to the signal wiring pattern 601 on the upper surface of the component 6 via the solder 161, conductor pattern 607, and a conductor 605 in a through-hole. Thus, an electric signal can be transmitted from the signal wiring pattern 501 of the component 5 to the signal wiring pattern 601 of the component 6.

In comparison to the first embodiment of the invention shown in FIGS. 3A to 4E, the second embodiment shown in FIGS. 6A to 7E differs in that the conductor 5001 of the component 5 is electrically connected directly to the ground conductors 502 and 504. Further, the conductor 5001 is not connected directly to the ground conductor 602 of the component 6 as shown in FIG. 7D, but the conductor 5001 is electrically connected to the ground conductor 602 via the ground conductor 504 and the solder 162, as shown in FIG. 7E.

Thus, the conductor 5001 of the component 5 prevents the emission of radio waves of the electric signal passing through the component 5, thus preventing the deterioration of the signal transmission characteristics in the high-frequency bands.

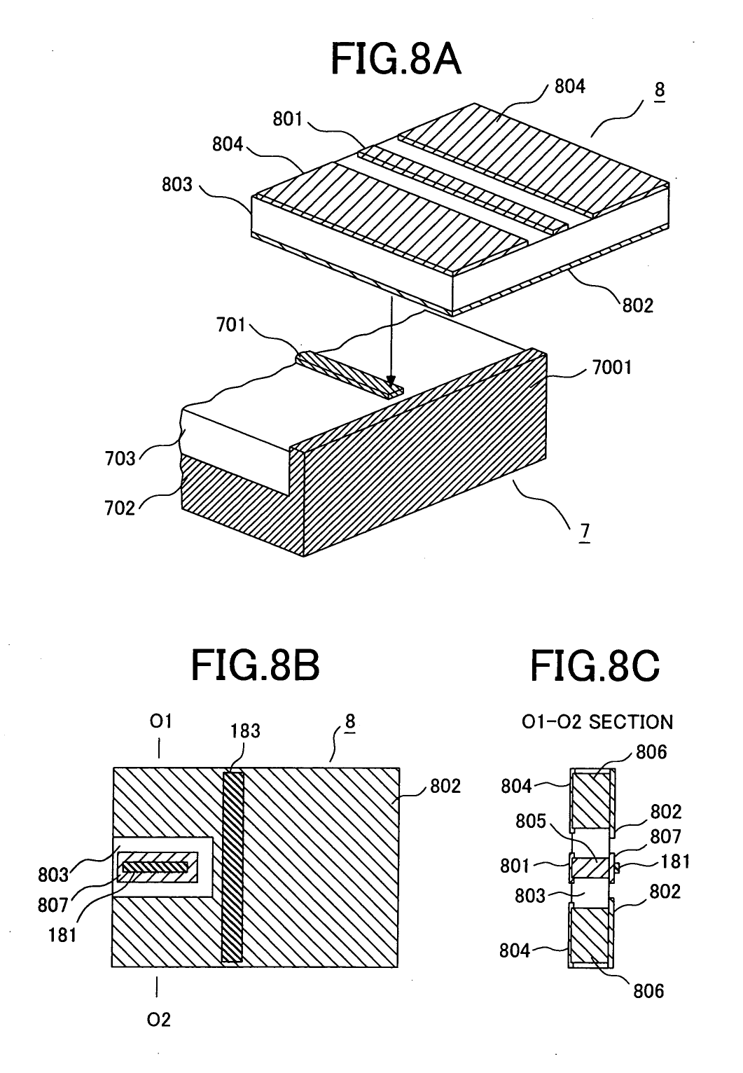

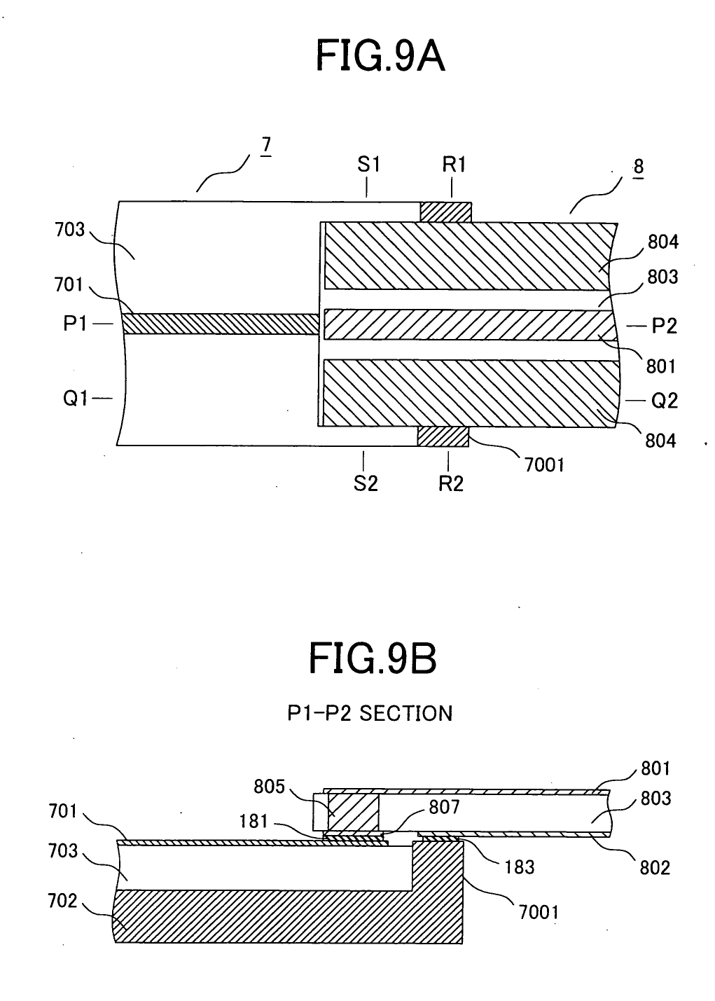

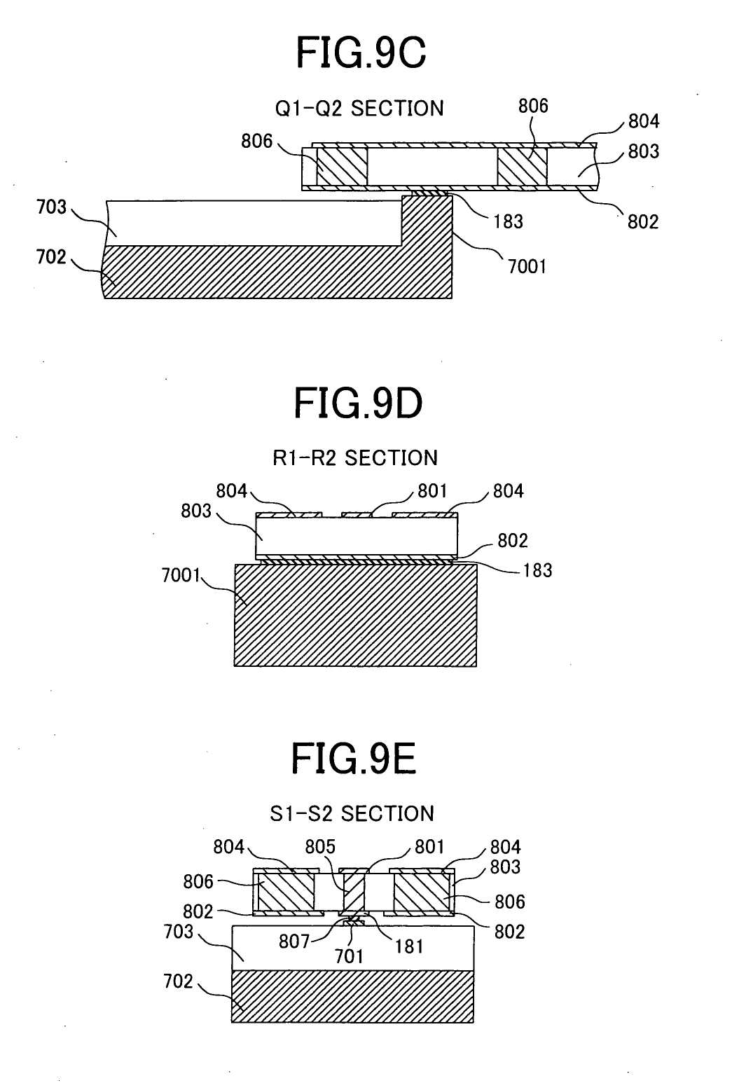

Now referring to FIGS. 8A through 9E, a third embodiment of the structure and method for connecting two transmission lines according to the invention will be described. One of transmission lines is a microstrip line and will be referred to as a component 7. The other of transmission lines is a coplanar line with a ground and will be referred to as a component 8. By connecting the signal wiring patterns of the two components 7 and 8 and by connecting the ground conductors of the two components 7 and 8, the two transmission lines are connected.

As shown in FIG. 8A, the lower component 7 includes a dielectric 703, a signal wiring pattern 701 disposed on an upper surface of the dielectric 703, and a ground conductor 702 disposed on a lower surface of the dielectric 703.

In the third embodiment, the lower component 7 further includes a conductor 7001 disposed on an end surface thereof. The conductor 7001 is disposed perpendicular to the signal wiring pattern 701, such that it covers an end surface of the dielectric 703. The conductor 7001 is electrically connected to the ground conductor 702.

The upper component 8 includes a dielectric 803, a signal wiring pattern 801 and a ground conductor 804 both disposed on an upper surface of the dielectric 803, and a ground conductor 802 disposed on a lower surface of the dielectric 803.

As shown in FIG. 8B, a conductor pattern 807 is disposed on the lower surface of the upper component 8. As shown in FIG. 8C, the conductor pattern 807 is connected to the signal wiring pattern 801 via a conductor 805 in a through-hole formed in the dielectric 803.

Solders 181 and 183 are disposed on the conductor pattern 807 and the ground conductor 802, respectively, on the lower surface of the component 8. These solders function to electrically and mechanically connect the conductors of the components 7 and 8.

Referring to FIGS. 9A to 9E, the structure and method for connecting the components 7 and 8 will be described in more detail. As shown in FIG. 9A, the components are arranged such that an end of the component 8 is superposed on an end of the component 7. As shown in FIG. 9B, the signal wiring pattern 701 on the upper surface of the component 7 is electrically connected to the conductor pattern 807 on the lower surface of the component 8 via the solder 181. As shown in FIG. 9C, the ground conductors 804 and 802 of the component 8 are electrically connected to each other via a conductor 806 in a through-hole formed in the dielectric 803.

Further, in the third embodiment, an upper surface of the conductor 7001 of the component 7 is electrically connected to the ground conductor 802 on the lower surface of the component 8 via the solder 183, as shown in FIGS. 9B, 9C, and 9D.

As shown in FIG. 9E, the signal wiring pattern 701 on the upper surface of the component 7 is electrically connected to the signal wiring pattern 801 on the upper surface of the component 8 via the solder 181, conductor pattern 807, and a conductor 805 in a through-hole. Thus, an electric signal can be transmitted from the signal wiring pattern 701 to the signal wiring pattern 801 of the component 8.

In comparison to the first and second embodiments, the third embodiment shown in FIGS. 8A to 9E differs in that the lower component 7 is a microstrip line having no ground conductor on the upper surface of the dielectric 703, and in that the upper component 8 is a coplanar line with a ground that has further a ground conductor on the upper surface of the dielectric 803. Further, the conductor 7001 is added to the end surface of the lower component 7 that corresponds to the end surface 3000 of the component 1 of the conventional example, and is electrically connected to the ground conductor 702.

In this structure too, the conductor 7001 prevents the emission of radio waves of the electric signal passing through the component 7, thus preventing the deterioration of the electric characteristics in high-frequency bands.

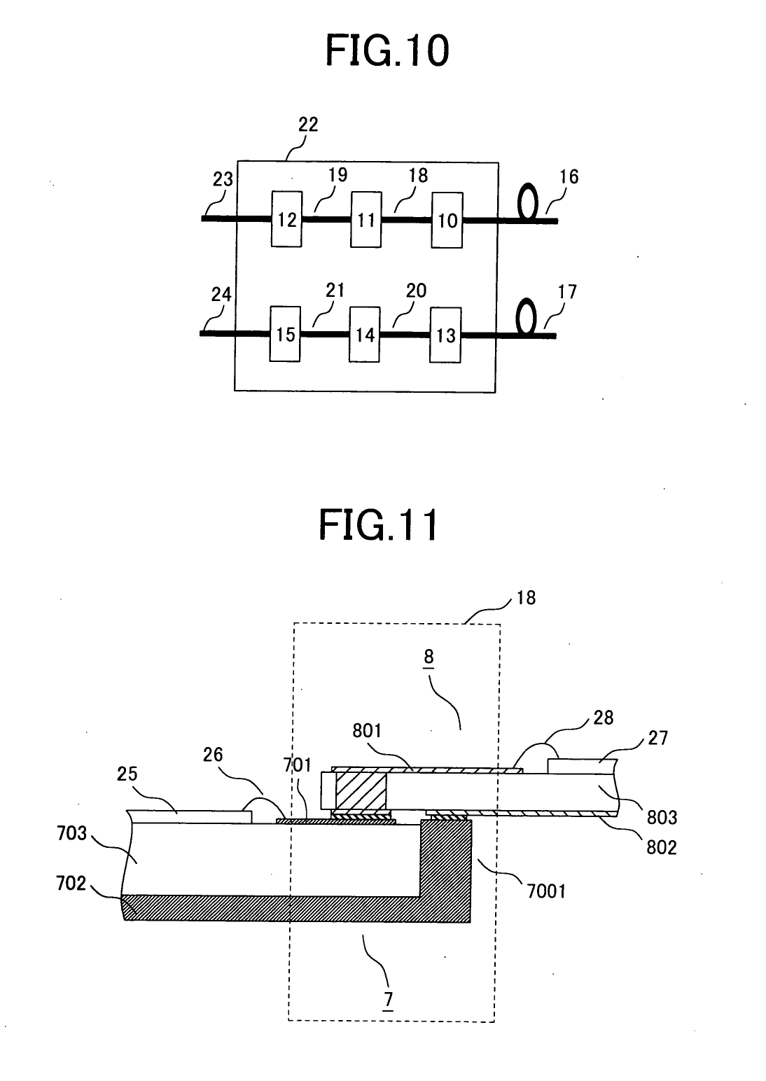

FIG. 10 shows an example of an optical transmission module to which the connection structure according to the invention can be applied. A plurality of parallel electric signals enter an optical transmission module 22 via a signal wiring pattern 23. The mutual phases of the signals are adjusted by a phase adjuster 12, and the signals are then converted into a single high-frequency signal by a multiplexer 11 before being transmitted to a light-emitting device 10. An optical signal emitted by the light-emitting device 10 is transmitted to the outside via an optical fiber cable 16. The optical signal introduced into the optical transmission module 22 via an optical fiber cable 17 is converted into a high-frequency signal by a photodetector 13. The signal is then converted into a plurality of parallel electric signals by a demultiplexer 14 and a phase adjuster 15, and the signals are transmitted to an external apparatus via a signal wiring pattern 24.

Of all the transmission lines connecting the devices making up the optical transmission module, a transmission line 18 between the multiplexer 11 and the light-emitting device 10 and a transmission line 20 between the light-emitting device 13 and the demultiplexer 14 carry high-frequency electric signals. Thus, it is preferable to apply the connection structure according to the invention to these inter-device transmission lines. Preferably, the connection structure of the invention may be applied to other portions, such as a transmission line 19 between the phase adjuster 12 and the multiplexer 11 and a transmission line 21 between the demultiplexer 14 and the phase adjuster 15.

FIG. 11 is a cross-sectional view of an example in which the connection structure described with reference to FIGS. 8A to 9E is applied to the inter-device transmission line 18 of the optical transmission module shown in FIG. 10.

The multiplexer 11 of FIG. 10 is formed in a semiconductor chip 25, of which a partial cross-section is shown in FIG. 11. A component 7 functions as a substrate for supporting the semiconductor chip 25 and also as a wiring lead. Specifically, the semiconductor chip 25 is mounted on a dielectric plate 703, and a pad of the semiconductor chip is electrically connected to a signal wiring pattern 701 via a bonding wire 26. On the other hand, the photodetector of FIG. 10 is formed in a semiconductor chip 27. A component 8 functions as a substrate for supporting the semiconductor chip 27 and also as a wiring lead. A pad on the chip 27 is electrically connected to a signal wiring pattern 801 via a bonding wire 28. The components 7 and 8 are similar in structure to the components 7 and 8, respectively, described with reference to FIGS. 8A to 9E. The structure for connecting them is also similar to that described by referring to FIGS. 8A to 9E. Thus, the end of the dielectric plate 703 of the component 7 is substantially covered by a conductor 7001 that is electrically connected to a ground conductor 702.

Thus, the technique according to the invention can be applied to the optical transmission module, which is one of network apparatuses. When the invention is applied to the optical transmission module, the signal transmission characteristics of the transmission lines can be satisfactorily maintained up to high-frequency bands, so that the performance of the relevant apparatus can be enhanced.

In the first, second and third embodiments, the transmission lines are either coplanar lines with grounds or microstrip lines. However, those skilled in the art will readily appreciate that the connection structure for transmission lines according to the present invention can be also applied to cases where the transmission lines are formed by strip lines.

It will be readily appreciated by those skilled in the art that the embodiments described above are merely exemplary and that various modifications or variations may be made within the scope and spirit of the invention as defined in the appended claims.

In accordance with the invention, the emission of radio waves of a high-frequency signal at a connection of transmission lines can be prevented.

In accordance with the invention, a transmission line structure can be realized that has good signal transmission characteristics up to high-frequency bands.

1. A connection structure for transmission lines comprising:
a first transmission line comprising a first dielectric plate and a first signal wiring pattern disposed on a surface of said first dielectric plate; and
a second transmission line comprising a second dielectric plate and a second signal wiring pattern disposed on a surface of said second dielectric plate, wherein
said first signal wiring pattern is electrically connected to said second signal wiring pattern near an end surface of said first transmission line, so that an electric signal can be transmitted from said first signal wiring pattern to said second signal wiring pattern,
said connection structure further comprising:
a conductor disposed on said end surface of said first transmission line such that it substantially covers said end surface of said first dielectric plate.

2-10. (canceled)
